(19) United States
(12) Patent Application Publication
(10) Pub. No.: US 2026/0119763 A1
(43) Pub. Date: Apr. 30, 2026

(54) CLOUD NATIVE METHOD AND SYSTEM FOR FPGA-BASED HARDWARE LOGIC EMULATION

(71) Applicant: INSTITUTE OF COMPUTING TECHNOLOGY, CHINESE ACADEMY OF SCIENCES, Beijing (CN)

(72) Inventors: Yisong CHANG, Beijing (CN); Yuxiao CHEN, Beijing (CN); Ke ZHANG, Beijing (CN); Mingyu CHEN, Beijing (CN); Yungang BAO, Beijing (CN)

(21) Appl. No.: 19/142,067

(22) PCT Filed: Mar. 16, 2023
(86) PCT No.: PCT/CN2023/081844

§ 371 Date: Jun. 20, 2025

(30) Foreign Application Priority Data
Dec. 23, 2022 (CN) 202211667431.4

(51) Int. Cl. G06F 30/331; G06F 30/333; G06F 30/347

(52) U.S. Cl. CPC G06F 30/331; G06F 30/333; G06F 30/347

(57) ABSTRACT

This invention proposes a cloud native method and system for FPGA-based hardware logic emulation, including: building a hardware logic emulation platform based on a loosely coupled FPGA cluster, and partitioning each FPGA node into a static logic region and a plurality of dynamic logic regions. Specifically, with a custom design tool, such an FPGA-based emulation platform obtains multiple cloud tenants'hardware logic Design Under Tests (DUTs) wraps an emulation control circuit to each DUT. Then FPGA configuration bitstream files that are deployable in each dynamic logic region are generated with the toolset. An emulation software is also employed on a tightly coupled general-purpose microprocessor in each FPGA node to control emulation operation of the DUT and to receive circuit status of DUTs in each dynamic logic region as emulation results for each tenant.

### CROSS-REFERENCE TO RELATED APPLICATIONS

This application is the U.S. National Stage entry of International Application No. PCT/CN2023/081844, filed on Mar. 16, 2023, which, in turn, claims priority to CN Patent Application No. 202211667431.4, filed on Dec. 23, 2022, both of which are hereby incorporated herein by reference in their entireties for all purposes.

### FIELD

The invention relates to the technical field of chip design, emulation and debugging, and in particular to a cloud native method and system for FPGA-based hardware logic emulation.

### BACKGROUND

Various processor chips are facing challenges of growing scale of logic design and continuously shortened time-to-market. Conventionally, during the design and debugging phase of the processor chips, software simulators are needed to debug the hardware logic design of the processor chips. Despite its full observability of each logic signal in a processor design, such a software-based method still faces slow logical simulation speed. As application scenarios continue to update and change, the design complexity of a processor and even the entire chip has increased significantly, resulting in exacerbated difficulties in logic verification and debugging.

Another method to verify and debug the processor logic designs is to use a kind of hardware programmable devices named FPGAs to build a prototype of the target processor design. With FPGA design tools, the processor hardware design needs to be synthesized and implemented into a programmable bitstream file leveraged to configure FPGA hardware logic circuits. As a real-world hardware implementation, the FPGA prototypingincreases functional evaluation speed. However, due to the extremely limited dedicated debugging resources in an FPGA chip, it is unable to fully record all logic signals'status in each clock cycle, making it difficult to expose a user-friendly debugging environment as that in a software simulator.

To balance the performance and observability in pre-silicon verification and evaluation, an FPGA-based logic emulation is a feasible solution. The FPGA-based logic emulator inserts a specific control circuit into the processor design under test, thereby using real hardware to obtain better emulation performance than software emulators, and using customized software tools to achieve a cycle-accurate and bit-accurate observation of all logic signals of the design under test. Nevertheless, the current dedicated FPGA-based logic emulation platform and supporting tools (such as Synopsys ZeBu and Aldec HES built on FPGA) are often expensive and complicated to use.

On the other hand, as the deployment scale of FPGA devices in data centers continues to grow, it has become an important trend to use FPGA as a type of public available cloud computing resource that can be shared and used for tenants to rent and deploy customized hardware accelerator designs on demand. Amazon AWS first launched rentable FPGA computing instances in 2016; China domestic internet leaders such as Alibaba Cloud, Tencent Cloud, and Huawei Cloud have also followed suit and launched FPGA public cloud infrastructure and rental services. Different from development methods of local FPGA, users cannot physically connect to cloud FPGA boards, making traditional FPGA hardware logic debugging methods unusable, and there is an urgent need to provide a cloud native FPGA hardware logic debugging method.

Although the existing dedicated FPGA-based logic emulation platform can provide a logic emulation rate of 1-10MHz for register transfer level (RTL) code or netlist, it still has the following problems:
1) in the existing FPGA emulation acceleration and prototype verification platforms, large scale FPGA chips or boards adopt a tightly coupled interconnection method, which is using the ordinary I/O pins of the FPGA chip for pin-to-pin data transmission through the time division multiplexing method. However, as the scale of the design under test continues to grow, the tightly coupled platform is limited by the fixed topological structure and cannot flexibly expand resources, thereby limiting the scale of the design under test that can support emulation acceleration or prototype verification. In particular, as the design scale continues to grow, the emulation acceleration platform with a limited-scale cannot meet the verification requirements, resulting in a reduced verification quality.
2) the existing FPGA-based emulation appliances and tools require high purchase costs, making chip design teams unable to purchase sufficient computing power for the emulation acceleration to meet team needs. On the one hand, the limited resources for the emulation acceleration prevents chip design teams to conduct large-scale verification of target designs, which reducing verification efficiency.

Problems faced by existing FPGA cloud hardware debugging methods:
1) although FPGA cloud has been commercialized on a large scale, the FPGA hardware logic debugging method on the cloud still depends on the traditional Embedded Logic Analyzer (ELA) method, and provides debugging control to users through a virtual debugging interface based on the network or PCIe interface (such as Xilinx XVC, etc.). However, the above method is similar to the traditional FPGA debugging method, which is not able to fully record all the logic signals'states of the design under test due to the relatively limited logic resource capacity inside the FPGA chip. At the same time, ELA's state monitoring of logic signals needs to be controlled by dedicated logic triggering conditions, and the cycle-accurate hardware logic operation state monitoring cannot be provided.
2) existing cloud-based FPGA computing resources are often provided to tenants in an exclusive manner and there may be a mode where multiple tenants share FPGAs in the future. However, the existing cloud-based FPGA debugging mechanism requires tenants to exclusively use ELA and related FPGA on-chip debugging resources and interfaces, which cannot support the hardware logic debugging needs of multiple tenants.

### SUMMARY

Specifically, the invention provides a cloud native hardware logic emulation method based on FPGA acceleration, including:
Step 1, building a hardware logic emulation acceleration platform based on a loosely coupled FPGA cluster, the acceleration platform includes a top of rack switch in a data center and a plurality of loosely coupled FPGA cluster racks, each of the loosely coupled FPGA cluster racks includes a switch and a plurality of FPGA nodes connected to the switch, each of the switches is connected to the top of rack switch in the data center;
Step 2, partitioning each of the FPGA nodes into a static logic area for bearing functions provided by the acceleration platform, and a plurality of dynamic logic areas with a same logic resource scale for bearing a plurality of user logic, obtaining hardware designs to be emulated for each of tenants of the current acceleration platform, inserting an emulation control circuit, performing operations of FPGA logic synthesis and placement and routing on the hardware designs inserted with the emulation control circuit, generating configuration files for the FPGA nodes to configure the dynamic logic areas of the FPGA nodes;
Step 3, running an emulation software on integrated processors in the FPGA nodes, controlling operation of the hardware designs on the FPGA nodes, the dynamic logic areas of each of the FPGA nodes generates emulation data and each of the FPGA nodes performs emulation data interaction with the other FPGA nodes through the static logic areas, and state data in circuits of the FPGA nodes are finally sent back to the tenants as emulation results through a user operation interface.

In the cloud native hardware logic emulation method based on FPGA acceleration, when inserting the emulation control circuit in step 2, identifying each clock-driven register and memory inside logics to be emulated, inserting a scan chain logic in sequence according to an identification order, and recording locations of each register and memory in the scan chain; generating a bitstream file that are deployable on cloud-based FPGAs according to the FPGA logic synthesis and placement and routing method; in an emulation acceleration running stage, after an emulation acceleration control software pauses an emulation circuit, state values of each register and memory are read out from the scan chain in sequence through an addressable control register, and the state values of each register and memory are determined according to the recorded location information of each register and memory in the scan chain.

In the cloud native hardware logic emulation method based on FPGA acceleration, when inserting the emulation control circuit in step 2, identifying each clock-driven register inside logics to be emulated, and generating a netlist name list of all register circuits; generating a constraint file for marking DONT_TOUCH for all the registers according to the obtained register netlist names to ensure that the marked register names are not modified during the FPGA logic synthesis stage; generating a bitstream file that are deploy able on cloud-based FPGAs according to the FPGA logic synthesis and placement and routing method; in the process of generating the bitstream file, generating a logic location file synchronously to mark location information of each register and memory on FPGA chips; in an emulation acceleration running stage, after an emulation acceleration control software pauses an emulation circuit, reading states of each register and memory inside the current FPGA by using a FPGA readback function and restoring determined output values of each register and memory in the user logic in conjunction with the logic location file.

In the cloud native hardware logic emulation method based on FPGA acceleration, the mode in which emulation data interact between the FPGA nodes in step 3 includes a hardware communication protocol stack located in the static logic area providing reliability assurance for cross-chip communication of the loosely coupled FPGA cluster; the protocol stack is used for a receiving terminal FGPA to generate an ACK response after receiving data shards, and notify a sending terminal FPGA of shard numbers that have been received, which indicating that data packets less than or equal to the current shard number have been received; before receiving the response, the sending terminal FPGA maintains all sent data shard windows; if the response is received within a specified time, the corresponding data packet can be released; otherwise, all the data shards in the shard windows are resent.

The invention further provides a cloud native hardware logic emulation system based on FPGA acceleration, including:

An acceleration platform creation module configured to build a hardware logic emulation acceleration platform based on a loosely coupled FPGA cluster, the acceleration platform includes a top of rack switch in a data center and a plurality of loosely coupled FPGA cluster racks, each of the loosely coupled FPGA cluster racks includes a switch and a plurality of FPGA nodes connected to the switch, each of the switches is connected to the top of rack switch in the data center;

A FPGA configuration module configured to partition each of the FPGA nodes into a static logic area for bearing functions provided by the acceleration platform, and a plurality of dynamic logic areas with a same logic resource scale for bearing a plurality of user logic, and use a customized tool chain in conjunction with the FPGA logic area partitioning method to obtain hardware designs to be emulated for each of tenants of the current acceleration platform, insert an emulation control circuit, perform operations of FPGA logic synthesis and placement and routing on the hardware designs inserted with the emulation control circuit, generate configuration files for the FPGA nodes to configure the dynamic logic areas of the FPGA nodes;

A FPGA emulation module configured to run an emulation software on tightly coupled integrated processors in the FPGA nodes, control operation of the hardware designs on the FPGA nodes, the dynamic logic areas of each of the FPGA nodes generates emulation data and each of the FPGA nodes performs emulation data interaction with the other FPGA nodes through the static logic areas to achieve a large-scale logic circuit emulation, and state data in circuits of the FPGA nodes are finally sent back to the tenants as emulation results.

In the cloud native hardware logic emulation system based on FPGA acceleration, when the FPGA configuration module inserting the emulation control circuit, identifying each clock-driven register and memory inside logics to be emulated, inserting a scan chain logic in sequence according to an identification order, and recording locations of each register and memory in the scan chain; generating a bitstream file that are deployable on cloud-based FPGAs according to the FPGA logic synthesis and placement and routing method; in an emulation acceleration running stage, after an emulation acceleration control software pauses an emulation circuit, state values of each register and memory are read out from the scan chain in sequence through an addressable control register, and the state values of each register and memory are determined according to the recorded location information of each register and memory in the scan chain.

In the cloud native hardware logic emulation system based on FPGA acceleration, when the FPGA configuration module inserting the emulation control circuit, identifying each clock-driven register inside logics to be emulated, and generating a netlist name list of all register circuits; generating a constraint file for marking DONT TOUCH for all the registers according to the obtained register netlist names to ensure that the marked register names are not modified during the FPGA logic synthesis stage; generating a bitstream file that are deployable on cloud-based FPGAs according to the FPGA logic synthesis and placement and routing method; in the process of generating the bitstream, generating a logic location file synchronously to mark location information of each register and memory on FPGA chips; in an emulation acceleration running stage, after an emulation acceleration control software pauses an emulation circuit, reading states of each register and memory inside the current FPGA by using a FPGA readback function and restoring determined output values of each register and memory in the user logic in conjunction with the logic location file.

In the cloud native hardware logic emulation system based on FPGA acceleration, the mode in which emulation data interact between the FPGA nodes in the FPGA emulation module includes a hardware communication protocol stack located in a static logic area providing reliability assurance for cross-chip communication of the loosely coupled FPGA cluster to support a larger-scale logic circuit emulation acceleration; the protocol stack is used for a receiving terminal FGPA to generate an ACK response after receiving data shards, and notify a sending terminal FPGA of shard numbers that have been received, which indicating that data packets less than or equal to the current shard number have been received; before receiving the response, the sending terminal FPGA maintains all sent data shard windows; if the response is received within a specified time, the corresponding data packet can be released; otherwise, all the data shards in the shard windows are resent.

The invention further provides a storage medium for storing programs executing any of the cloud native hardware logic emulation method based on FPGA acceleration.

The invention further provides a client for any of the cloud native hardware logic emulation system based on FPGA acceleration.

As can be known from the above technical solution, advantages of the invention are as follows:

The present invention provides loosely coupled and scalable FPGA clusters to users in the form of computing power Infrastructure-as-a-Service, and abstracts FPGA emulation acceleration tools into a series of software services, allows users to quickly customize a hardware debugging process based on emulation acceleration according to the target design condition, reduces the deployment cost and usage threshold for chip design users, and improves emulation verification performance based on large-scale cloud computing power. At the same time, the relevant methods of the present invention can be applied to cloud FPGA hardware logic debugging in multi-tenant scenarios, reducing the dependence of existing cloud FPGA debugging interfaces on FPGA on-chip ELA resources, allowing multiple tenants can concurrently observe all logic signal states of their respective target logic designs.

### BRIEF DESCRIPTION OF THE DRAWINGS

FIG. 1 is a schematic diagram of a structure of a loosely coupled FPGA cluster of the invention.

FIG. 2 is a schematic diagram of a logic circuit after splitting.

FIG. 3 is a schematic diagram of an emulation process of the invention.

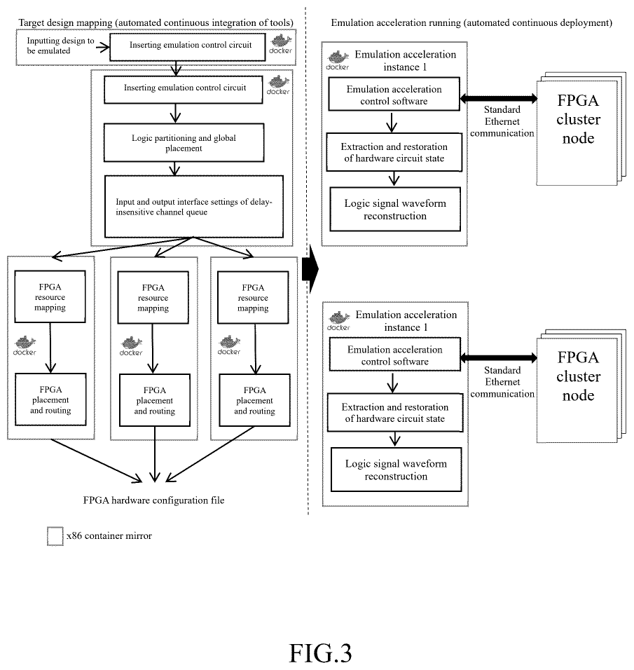

FIG. 4 is a diagram illustrating an embodiment of the invention.

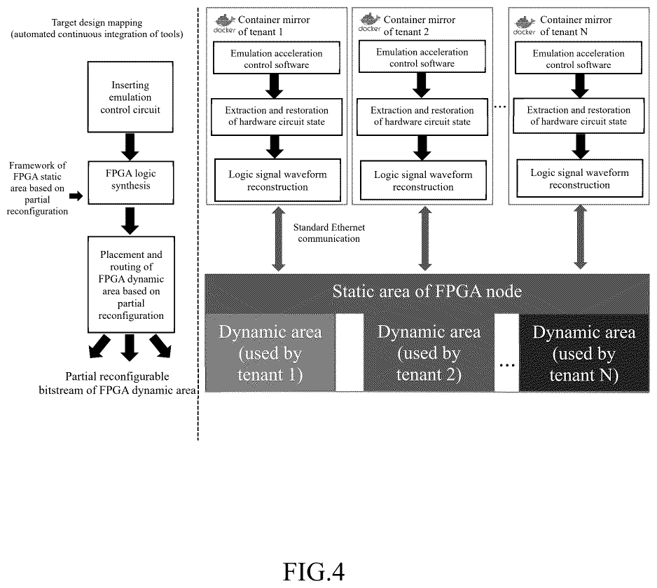

### DETAILED DESCRIPTION

The invention can provide a cycle accurate and bit accurate full-signal-level hardware debugging method for processor chip logic design based on FPGA (Field Programmable Gate Array) acceleration, which not only avoids the time overhead caused by using logic emulation software tools, but also solves the problem of limited number of adjustable signals in FPGA prototype verification of the processor chip design. At the same time, the invention can also provide a hardware-logic-signal-level debugging method for FPGA public cloud, enriching the technical means of FPGA public cloud for application acceleration debugging.

The invention aims to improve the hardware debugging efficiency of large-scale hardware logic design, and provides a creation method for cloud native logic emulation FPGA acceleration platform, so that the operating state of the target hardware circuit can be monitored at high speed with cycle accuracy and bit accuracy, and can provide users with elastic and scalable emulation acceleration computing power and software tool services, thereby lowering the threshold for using logic emulation acceleration tools.

In addition, the above methods can also eliminate tenants'reliance on the ELA when debugging hardware logic in existing commercial public FPGA cloud services, thereby providing a new method for cloud FPGA hardware logic debugging and providing debugging methods for future scenarios where multiple tenants share and use cloud FPGA. Therefore, the invention includes the following key technical points:
Key point 1: The cloud-enabled infrastructure service platform for hardware logic emulation acceleration built on loosely coupled FPGA clusters breaks through the scalability limitations of traditional dedicated FPGA emulation acceleration platforms through standard network interconnection;
Key point 2: A cloud-native encapsulating method for logic emulation FPGA acceleration tool, including 1) customized programming of tool usage based on continuous integration technology, and 2) decoupling the tool process links through container technology, disassembling the single FPGA emulation acceleration tool into a series of generalized functions;
Key point 3: A hardware logic debugging method on FPGA public cloud environment for multi-tenant scenarios, which can support multiple tenants to perform FPGA hardware logic debugging concurrently.

To enable the above features and effects of the invention to set forth clearer, hereinafter the embodiments are provided, and detailed descriptions are made with reference to the accompanying drawings.

### 1. Cloud-Enabled Infrastructure for Hardware Logic Emulation Acceleration Built on Loosely Coupled FPGA Clusters

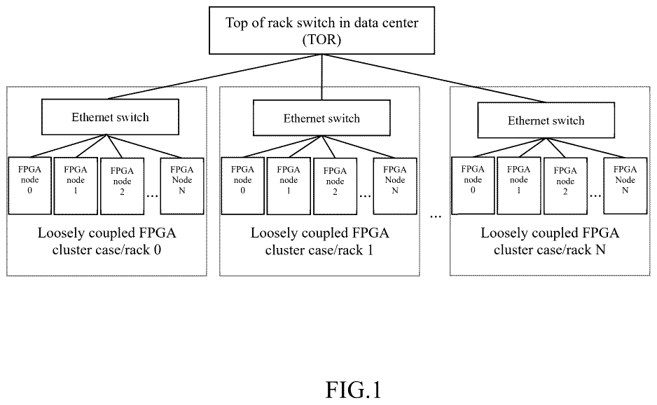

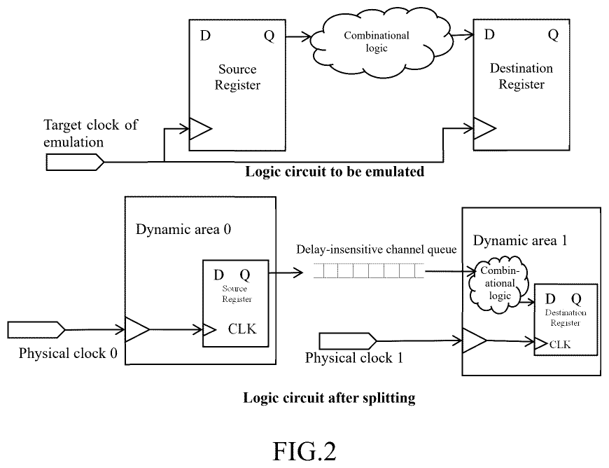

A circuit board built with one FPGA chip as the core is one FPGA node. Cloud service providers pre-partitions logic areas in the FPGA into a static logic area and a plurality of dynamic logic areas. The static logic area is used to implement the functions provided by the cloud service providers and remains unchanged during the service; the plurality of dynamic logic areas is used to bear a user logic and can be reprogrammed according to the user needs to implement different functions. The invention provides a loosely coupled FPGA cluster, which is interconnected based on the standard Ethernet interface and the existing data center network infrastructure, and FPGA resources can be flexibly added to the cluster as needed. To achieve the hardware logic emulation acceleration based on the loosely coupled FPGA cluster, as shown in FIG. 1, the invention provides the following technical solutions:
1) Static partition and dynamic use of programmable logic areas in the FPGA node: based on partial reconfiguration technology, FPGA node is partitioned into a static logic area and a plurality of dynamic logic areas with a same logic resource scale. The design to be tested can occupy one to multiple dynamic logic areas. The static logic area supports the coordinated operation between the dynamic logic areas within the same FPGA chip Die, and the static logic area supports the coordinated operation between the dynamic logic areas within different FPGA chip Dies, and the static logic area supports the coordinated operation between the dynamic logic areas within different FPGA chips.
2) Delay-insensitive cross-dynamic logic area hardware logic deployment: as shown in FIG. 2, a target hardware logic partitioning method based on delay-insensitive channel queues is used. The method splits the complete logic design to be emulated into several independent sub-modules that do not create data dependency by encapsulating an output of a register into a data packet and inserting it into the delay-insensitive channel queue. Different sub-modules can be deployed in the different dynamic logic areas and exchange data through delay-insensitive channel queues under the drive of different clocks. Within a target clock cycle of an emulation, each module will write a valid register output data packet to a delay-insensitive output channel queue, and read a valid data packet transmitted from other sub-modules from a delay-insensitive input channel queue.

For one of the sub-modules, when the corresponding delay-insensitive input channel is empty or the delay-insensitive output channel is full, the sub-module will suspend emulation. At this time, to ensure that each register in the sub-module can maintain the current logic state, the Clock-Gating needs to be performed to the physical clock. The Clock-Gating process uses a clock gating element on the FPGA to control the physical clock signal to no longer flip, so that each register stops updating the state, and the output value at the Q terminal does not change with the input value at the D terminal.
3) Reliability assurance for cross-chip communication of loosely coupled FPGA cluster: the FPGA node-to-node communication based on loosely coupled Ethernet physical paths in the data center cannot assure the reliability of communication, and network packet loss can easily occur. However, the FPGA acceleration of hardware logic emulation has extremely strict requirements on data transmission and data loss is not permitted. Therefore, the invention provides a reliability assurance mechanism for node-to-node communication of the loosely coupled FPGA cluster based on a streamlined TCP protocol by designing a customized hardware protocol stack that supports a data retransmission mechanism to ensure the network packet transmission with zero packet loss and ensure platform robustness.

The reliability assurance is performed by using data shard numbers of the TCP protocol in conjunction with the ACK response mechanism specified in the TCP protocol. After receiving the data shard, a receiving terminal will generate an ACK response to notify the sender of shard numbers that have been received (indicating that data packets less than or equal to the current shard number have been received). Before receiving the response, the sender needs to maintains all sent data shard windows. If the response is received within a specified time, the corresponding data packet can be released (i.e. the sliding window); otherwise, all the data shards in the shard windows are resent.

### 2. A Cloud-Native Encapsulating Method for Logic Emulation FPGA Acceleration Tool

To make full use of the characteristics of rich computing resources and elastic scalability in cloud computing environment, the invention provides the following technical improvements:
1) Using continuous integration technology to decouple the workflow of FPGA-accelerated logic emulation tools into two stages of ‘target design mapping’ and ‘emulation acceleration running’. Languages of continuous integration tool (such as YML scripts) can be used in each stage to customize the operating environment, input and output files, and file saving methods of each step;
2) Further decoupling the steps in one of the stages, and using container technology to containerize its operating environment (including program libraries, tool sets, etc.) to form a series of generalized functions that can be directly deployed and run;
3) Based on cloud infrastructure resources and container resource scheduling, multiple emulation instances run concurrently on the cloud platform can be supported, which improves the concurrent service capabilities of the FPGA acceleration for hardware logic emulation.

### 3. A Hardware Logic Debugging Method on FPGA Public Cloud Environment for Multi-Tenant Scenarios

Applying FPGA emulation acceleration to hardware logic debugging on FPGA public cloud for multi-tenant scenarios can be divided into two stages of ‘target design mapping’ and ‘emulation acceleration running’. In the ‘target design mapping” stage, an emulation control circuit is inserted into the user's hardware design that is to be debugged, and the circuit is configured to receive commands from an emulation acceleration control software, control the operating state of the hardware design, and access the state data inside the hardware design. Subsequently, performing operations of FPGA logic synthesis and placement and routing on the hardware design inserted with the control circuit, generating bitstream files that can be configured on the FPGA.

In the ‘emulation acceleration running’ stage, processors integrated in the FPGA run the emulation acceleration control software to control the operation of the hardware design on the FPGA and allow users to pause and save the state data inside the circuit at any time through a user operation interface. By storing the state data in the form of a file, the state data can be loaded in the emulation software to reproduce the circuit state information from the time of saving, and finally can be generated and saved as user-observable wave files, which are provided to users for logical behavior observation, thereby supporting users to perform hardware logic debugging on the FPGA public cloud.

There are two specific methods for obtaining and saving the state of hardware logic circuits:

### 1) Implementation Method 1: Logic State Monitoring Based on Scan Chain Insertion

Step 1: in the stage when the emulation control circuit is inserted during the target design mapping, identifying each clock-driven register and memory inside logics to be emulated, inserting a scan chain logic in sequence according to an identification order, and recording locations of each register and memory in the scan chain.
Step 2: generating a bitstream file that are deployable on cloud-based FPGAs according to the logic synthesis and placement and routing method of the existing FPGA public cloud.
Step 3: in the emulation acceleration running stage, after the emulation acceleration control software pauses the emulation circuit, state values of each register and memory are read out from the scan chain in sequence through an addressable control register. The state values of each register and memory are determined according to the recorded location information of each register and memory in the scan chain.

### 2) Implementation Method 2: Logic State Monitoring Based on FPGA Readback Function

Step 1: in the stage when the emulation control circuit is inserted during the target design mapping, identifying each clock-driven register inside logics to be emulated, and generating a netlist name list of all register circuits.
Step 2: generating a constraint file for marking DONT TOUCH for all the registers according to the obtained register netlist names to ensure that the marked register names are not modified during the FPGA logic synthesis stage.
Step 3: generating a bitstream file that are deployable on cloud-based FPGAs according to the logic synthesis and placement and routing method of the existing FPGA public cloud; in the process of generating the bitstream, generating a logic location (11) file synchronously to mark location information of each register and memory on FPGA chips.
Step 4: in the emulation acceleration running stage, after the emulation acceleration control software pauses the emulation circuit, reading states of each register and memory inside the current FPGA by using a FPGA readback function and restoring determined output values of each register and memory in the user logic in conjunction with the extracted 11 file in the step 3.

Hereinafter is a system embodiment corresponding to the above-mentioned method embodiments, and this embodiment may be implemented in cooperation with the above embodiments. Relevant technical details mentioned in the above embodiments are still effective in this embodiment, and in order to avoid repetition, no details are described here. Correspondingly, relevant technical details mentioned in this embodiment also may be applied to the above embodiments.

The invention further provides a cloud native hardware logic emulation system based on FPGA acceleration, including:

An acceleration platform creation module configured to build a hardware logic emulation acceleration platform based on a loosely coupled FPGA cluster, the acceleration platform includes a top of rack switch in a data center and a plurality of loosely coupled FPGA cluster racks, each of the loosely coupled FPGA cluster racks includes a switch and a plurality of FPGA nodes connected to the switch, each of the switches is connected to the top of rack switch in the data center;

A FPGA configuration module configured to partition each of the FPGA nodes into a static logic area for bearing functions provided by the acceleration platform, and a plurality of dynamic logic areas with a same logic resource scale for bearing a user logic, and use a customized tool chain in conjunction with the FPGA logic area partitioning method to obtain hardware designs to be emulated for each of tenants of the current acceleration platform, insert an emulation control circuit, perform operations of FPGA logic synthesis and placement and routing on the hardware designs inserted with the emulation control circuit, generate configuration files for the FPGA nodes to configure the dynamic logic areas of the FPGA nodes;

A FPGA emulation module configured to run the emulation software on tightly coupled integrated processors in the FPGA nodes, control operation of the hardware designs on the FPGA nodes, the dynamic logic areas of each of the FPGA nodes generates emulation data and each of the FPGA nodes performs emulation data interaction with the other FPGA nodes through the static logic areas to achieve a large-scale logic circuit emulation, and state data in circuits of the FPGA nodes are finally sent back to the tenants as emulation results.

In the cloud native hardware logic emulation system based on FPGA acceleration, when the FPGA configuration module inserting the emulation control circuit, identifying each clock-driven register and memory inside logics to be emulated, inserting a scan chain logic in sequence according to an identification order, and recording locations of each register and memory in the scan chain; generating a bitstream file that are deployable on cloud-based FPGAs according to the FPGA logic synthesis and placement and routing method; in the emulation acceleration running stage, after the emulation acceleration control software pauses the emulation circuit, the state values of each register and memory are read out from the scan chain in sequence through the addressable control register, and the state values of each register and memory are determined according to the recorded location information of each register and memory in the scan chain.

In the cloud native hardware logic emulation system based on FPGA acceleration, when the FPGA configuration module inserting the emulation control circuit, identifying each clock-driven register inside the logics to be emulated, and generating the netlist name list of all register circuits; generating the constraint file for marking DONT_TOUCH for all the registers according to the obtained register netlist names to ensure that the marked register names are not modified during the FPGA logic synthesis stage; generating a bitstream file that are deployable on cloud-based FPGAs according to the FPGA logic synthesis and placement and routing method; in the process of generating the bitstream, generating the logic location file synchronously to mark location information of each register and memory on FPGA chips; in the emulation acceleration running stage, after the emulation acceleration control software pauses the emulation circuit, reading the states of each register and memory inside the current FPGA by using a FPGA readback function and restoring the determined output values of each register and memory in the user logic in conjunction with the logic location file.

In the cloud native hardware logic emulation system based on FPGA acceleration, the mode in which emulation data interact between the FPGA nodes in the FPGA emulation module includes a hardware communication protocol stack located in a static logic area providing reliability assurance for cross-chip communication of the loosely coupled FPGA cluster to support a larger-scale logic circuit emulation acceleration; the protocol stack is used for a receiving terminal FGPA to generate the ACK response after receiving the data shards, and notify a sending terminal FPGA of the shard numbers that have been received, which indicating that the data packets less than or equal to the current shard number have been received; before receiving the response, the sending terminal FPGA maintains all the sent data shard windows; if the response is received within the specified time, the corresponding data packet can be released; otherwise, all the data shards in the shard windows are resent.

The invention further provides a storage medium for storing programs executing any of the cloud native hardware logic emulation method based on FPGA acceleration.

The invention further provides a client for any of the cloud native hardware logic emulation system based on FPGA acceleration.

### INDUSTRIAL APPLICABILITY

The invention provides a cloud native hardware logic emulation method and system based on FPGA acceleration, including: building the hardware logic emulation acceleration platform based on the loosely coupled FPGA cluster, and partitioning each of the FPGA nodes into the static logic area for bearing functions provided by the acceleration platform and the plurality of dynamic logic areas with the same logic resource scale for bearing the target logic circuit to be emulated; wherein the supporting customized tool can obtain hardware designs to be emulated for each of tenants of the current acceleration platform and insert the emulation control circuit; the supporting tool can generate FPGA configuration files that are deploy able on the plurality of dynamic logic areas; running the emulation software on tightly coupled integrated processors in the FPGA nodes, controlling operation of the hardware designs on the FPGA nodes, and the dynamic logic areas of each of the FPGA nodes generate emulation data and the state data in circuits of the FPGA nodes are sent back to the tenants as the emulation results; and the static logic areas of each of the FPGA nodes perform emulation data interaction with the other FPGA nodes to support a large-scale logic circuit emulation.

1. A cloud native method for FPGA-based hardware logic emulation, wherein including:
Step 1, building a hardware logic emulation acceleration platform based on a loosely coupled FPGA cluster, the acceleration platform includes a top of rack switch in a data center and a plurality of loosely coupled FPGA cluster racks, each of the loosely coupled FPGA cluster racks includes a switch and a plurality of FPGA nodes connected to the switch, each of the switches is connected to the top of rack switch in the data center;
Step 2, partitioning each of the FPGA nodes into a static logic area for bearing functions provided by the acceleration platform, and a plurality of dynamic logic areas with a same logic resource scale for bearing a plurality of user logic, using a customized tool chain in conjunction with the FPGA logic area partitioning method to obtain hardware designs to be emulated for each of tenants of the current acceleration platform, inserting an emulation control circuit, performing operations of FPGA logic synthesis and placement and routing on the hardware designs inserted with the emulation control circuit, and generating configuration files for the FPGA nodes to configure the dynamic logic areas of the FPGA nodes;
Step 3, running an emulation software on tightly coupled integrated processors in the FPGA nodes, controlling operation of the hardware designs on the FPGA nodes, the dynamic logic areas of each of the FPGA nodes generates emulation data and each of the FPGA nodes performs emulation data interaction with the other FPGA nodes through the static logic areas to achieve a large-scale logic circuit emulation, and state data in circuits of the FPGA nodes are finally sent back to the tenants as emulation results.

2. The cloud native method for FPGA-based hardware logic emulation according to claim 1, wherein when inserting the emulation control circuit in step 2, identifying each clock-driven register and memory inside a logic to be emulated, inserting a scan chain logic in sequence according to an identification order, and recording locations of each register and memory in the scan chain; generating a bitstream file that are deployable on cloud-based FPGAs according to the FPGA logic synthesis and placement and routing method; in an emulation acceleration running stage, after an emulation acceleration control software pauses an emulation circuit, state values of each register and memory are read out from the scan chain in sequence through an addressable control register, and the state values of each register and memory are determined according to the recorded location information of each register and memory in the scan chain.

3. The cloud native method for FPGA-based hardware logic emulation according to claim 1, wherein when inserting the emulation control circuit in step 2, identifying each clock-driven register inside logics to be emulated, and generating a netlist name list of all register circuits; generating a constraint file for marking DONT_TOUCH for all the registers according to the obtained register netlist names to ensure that the marked register names are not modified during the FPGA logic synthesis stage; generating a bitstream file that are deployable on cloud-based FPGAs according to the FPGA logic synthesis and placement and routing method; in the process of generating the bitstream file, generating a logic location file synchronously to mark location information of each register and memory on FPGA chips; in an emulation acceleration running stage, after an emulation acceleration control software pauses an emulation circuit, reading states of each register and memory inside the current FPGA by using a FPGA readback function and restoring determined output values of each register and memory in the user logic in conjunction with the logic location file.

4. The cloud native method for FPGA-based hardware logic emulation according to claim 1, wherein the mode in which emulation data interact between the FPGA nodes in step 3 includes a hardware communication protocol stack located in a static logic area providing reliability assurance for cross-chip communication of the loosely coupled FPGA cluster; the protocol stack is used for a receiving terminal FGPA to generate an ACK response after receiving data shards, and notify a sending terminal FPGA of shard numbers that have been received, which indicating that data packets less than or equal to the current shard number have been received; before receiving the response, the sending terminal FPGA maintains all sent data shard windows; if the response is received within a specified time, the corresponding data packet can be released; otherwise, all the data shards in the shard windows are resent.

5. A cloud native hardware system for FPGA-based hardware logic emulation, wherein including,
An acceleration platform creation module configured to build a hardware logic emulation acceleration platform based on a loosely coupled FPGA cluster, the acceleration platform includes a top of rack switch in a data center and a plurality of loosely coupled FPGA cluster racks, each of the loosely coupled FPGA cluster racks includes a switch and a plurality of FPGA nodes connected to the switch, each of the switches is connected to the top of rack switch in the data center;
A FPGA configuration module configured to partition each of the FPGA nodes into a static logic area for bearing functions provided by the acceleration platform, and a plurality of dynamic logic areas with a same logic resource scale for bearing a plurality of user logic, using a customized tool chain in conjunction with the FPGA logic area partitioning method to obtain hardware designs to be emulated for each of tenants of the current acceleration platform, inserting an emulation control circuit, performing operations of FPGA logic synthesis and placement and routing on the hardware designs inserted with the emulation control circuit, and generating configuration files for the FPGA nodes to configure the dynamic logic areas of the FPGA nodes;
A FPGA emulation module configured to run an emulation software on tightly coupled integrated processors in the FPGA nodes, controlling operation of the hardware designs on the FPGA nodes, the dynamic logic areas of each of the FPGA nodes generates emulation data and each of the FPGA nodes performs emulation data interaction with the other FPGA nodes through the static logic areas to achieve a large-scale logic circuit emulation, and state data in circuits of the FPGA nodes are finally sent back to the tenants as emulation results.

6. The cloud native hardware system for FPGA-based hardware logic emulation according to claim 5, wherein when the FPGA configuration module inserting the emulation control circuit, identifying each clock-driven register and memory inside a logic to be emulated, inserting a scan chain logic in sequence according to an identification order, and recording locations of each register and memory in the scan chain; generating a bitstream file that are deployable on cloud-based FPGAs according to the FPGA logic synthesis and placement and routing method; in an emulation acceleration running stage, after an emulation acceleration control software pauses an emulation circuit, state values of each register and memory are read out from the scan chain in sequence through an addressable control register, and the state values of each register and memory are determined according to the recorded location information of each register and memory in the scan chain.

7. The cloud native hardware system for FPGA-based hardware logic emulation according to claim 5, wherein when the FPGA configuration module inserting the emulation control circuit, identifying each clock-driven register inside logics to be emulated, and generating a netlist name list of all register circuits; generating a constraint file for marking DONT TOUCH for all the registers according to the obtained register netlist names to ensure that the marked register names are not modified during the FPGA logic synthesis stage; generating a bitstream file that are deployable on cloud-based FPGAs according to the FPGA logic synthesis and placement and routing method; in the process of generating the bitstream file, generating a logic location file synchronously to mark location information of each register and memory on FPGA chips; in an emulation acceleration running stage, after an emulation acceleration control software pauses an emulation circuit, reading states of each register and memory inside the current FPGA by using a FPGA readback function and restoring determined output values of each register and memory in the user logic in conjunction with the logic location file.

8. The cloud native hardware system for FPGA-based hardware logic emulation according to claim 5, wherein the mode in which emulation data interact between the FPGA nodes in the FPGA emulation module includes a hardware communication protocol stack located in a static logic area providing reliability assurance for cross-chip communication of the loosely coupled FPGA cluster to support a larger-scale logic circuit emulation acceleration; the protocol stack is used for a receiving terminal FGPA to generate an ACK response after receiving data shards, and notify a sending terminal FPGA of shard numbers that have been received, which indicating that data packets less than or equal to the current shard number have been received; before receiving the response, the sending terminal FPGA maintains all sent data shard windows; if the response is received within a specified time, the corresponding data packet can be released; otherwise, all the data shards in the shard windows are resent.

9. A storage medium for storing programs executing the cloud native method for FPGA-based hardware logic emulation according to claim 1.

10. (canceled)
